(19) United States
(12) Patent Application Publication
(10) Pub. No.: US 2009/0091036 A1
(43) Pub. Date: Apr. 9, 2009

(54) Wafer structure with a buffer layer

(75) Inventors: Chih-Hsing Chen, Kaohsiung (TW); Tai-Yuan Huang, Kaohsiung (TW)

Correspondence Address: BACON & THOMAS, PLLC, 625 SLATERS LANE, FOURTH FLOOR, ALEXANDRIA, VA, 22314-1176, US

(73) Assignee: Advanced Semiconductor Engineering, Inc., Kaohsiung (TW)

(21) Appl. No.: 12/285,260

(22) Filed: Oct. 1, 2008

(30) Foreign Application Priority Data
Oct. 3, 2007 (TW) 96137179

(51) Int. Cl. H01L 23/532

(52) U.S. Cl. 257/770; 257/E23.157

(57) ABSTRACT

A wafer structure with a buffer layer is provided. The wafer structure comprises a wafer which has at least one pad formed thereon, a passivation layer formed on the wafer for partially exposing the at least one pad, a buffer layer formed on the passivation layer and the pad, and an under bump metallurgy (UBM) formed on the buffer layer. The buffer layer comprises a thickness-increased inner buffering member made from aluminum and located between the UBM and the pad to enhance the shock-absorbing ability of the wafer in a drop test to avoid the conductive bump bonded to a substrate coming off or cracking. The invention can also enhance the bonding between the conductive bump and the UBM. The buffer layer may further comprise an outer buffering member made of polyimide, coated on the passivation layer and partially arranged between the UBM and the passivation layer.

This application claims the benefit of Taiwan application Serial No. 96137179, filed Oct. 3, 2007, the subject matter of which is incorporated herein by reference.

### BACKGROUND OF THE INVENTION

1. Field of the Invention

The invention relates in general to a wafer structure, and more particularly to a wafer structure with a buffer layer added to the pad of the wafer to enhance the structural strength of the wafer, avoid the conductive bumps coming off and enhance the bonding between the pad and the under bump metallurgy (UBM).

2. Description of the Related Art

There are three common bonding methods used in semiconductor packaging process, namely wire bonding, tap automated bonding and flip chip bonding. To meet requirements for lightweight, thinness, simplicity and compactness of electronic products, semiconductor chips with smaller volume but high pin counts are developed and provided. However, the volume of the package after wire bonding or tap automated bonding becomes larger and cannot meet the requirement for high pin counts. Thus, flip chip bonding is a better choice.

FIG. 1 shows a perspective of a conventional wafer structure fabricated according to flip chip bonding process. The wafer structure comprises a wafer 102, wherein at least one pad 104 is disposed on one surface (such as the rear surface) of the wafer 102. Despite the fact that only one pad 104 is illustrated in FIG. 1, anyone who is skilled in related techniques will understand that normally a plurality of pads 104 is disposed on the wafer 102. Besides, one lateral surface of the wafer 102 is covered by a passivation layer 106. The passivation layer 106 has a plurality of opening portions corresponding to the pads 104 respectively for exposing the pads 104 to the passivation layer 106. An UBM 112 is disposed in each opening portion of the passivation layer 106 and electrically connected with the pads 104 exposed to the opening portion.

In conventional flip chip bonding process, beside the structure mentioned above, a conductive bump is further disposed on the UBM 112. The conductive bump is electrically connected with the UBM 112 and further can be used to bond to a substrate in subsequent manufacturing process so that the substrate is electrically connected with the wafer 102 via the conductive bump, the UBM 112 and the pad 104. Thus, the flip chip bonding process is completed.

Despite the fact that the wafer structure disclosed above has been widely used in the industry of wafer packaging and is indispensable to the development of the packaging industry, the above wafer structure still needs to be improved further. The above wafer structure has the following disadvantages:

First, as the conductive bump disposed on the UBM 112 is usually made of lead-free solder ball which is hard but brittle, the poor shock-absorbing ability in a drop test leads to the crack of the lead-free solder ball. As a result, the wafer structure has poor anti-shocking ability and may easily be damaged in collision.

Secondly, the conductive bump used for electrically connecting the wafer to the substrate may easily come off the UBM 112, causing the yield rate in the flip chip bonding process to decrease.

### SUMMARY OF THE INVENTION

The invention is directed to a wafer structure with a buffer layer to enhance the shock-absorbing ability of the wafer structure in a drop test to avoid the conductive bump bonded to a substrate coming off or cracking.

According to a first aspect of the present invention, a wafer structure with a buffer layer is provided. The thickness of aluminum used in an aluminum pad is increased to enhance the bonding ability between the conductive bumps and the UBM.

According to a second aspect of the present invention, a wafer structure with a buffer layer is provided. The wafer structure with a buffer layer comprises:

A wafer comprising at least one pad made of aluminum;

A passivation layer disposed on the wafer for partially exposing the at least one pad and covering a portion of the pad;

An outer buffer member coated on the passivation layer, wherein the outer buffering member is made of polyimide;

An inner buffering member formed on the at least one pad by electroless-plating aluminum, wherein the thickness of the inner buffering member is at least larger than 3 micrometers, and a portion of the passivation layer and a portion of the outer buffer member are further covered by the inner buffering member; and

An UBM disposed on the inner buffering member for covering a portion of the outer buffering member, wherein the UBM is made of a material selected from a group consisting of nickel, gold, palladium, titanium, vanadium and an alloy thereof.

According to a third aspect of the present invention, a wafer structure is provided. The wafer structure comprises:

A wafer comprising at least one pad made of aluminum;

A passivation layer disposed on the wafer for exposing the at least one pad and covering a portion of the pad;

An inner buffering member formed on the at least one pad by electroless-plating aluminum, wherein the thickness of the inner buffering member is at least larger than 3 micrometers, and a portion of the passivation layer is covered by the inner buffering member; and

An UBM disposed on the inner buffering member for covering a portion of the passivation layer, wherein the UBM is made of a material selected from a group consisting of nickel, gold, palladium, titanium, vanadium and an alloy thereof

The invention has the following advantages: (a) A buffer layer is added between the pad and the UBM to enhance the structural strength and the shock-absorbing ability of the wafer. (b) The bonding ability between the conductive bumps and the UBM is enhanced.

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) shows a perspective of a conventional wafer structure;

FIG. 2 shows a perspective of a wafer structure according to a first embodiment of the invention;

FIG. 3 shows a perspective of a wafer structure according to a second embodiment of the invention;

FIG. 4 shows a perspective of a wafer structure according to a third embodiment of the invention;

FIG. 5 shows a perspective of a wafer structure according to a fourth embodiment of the invention;

FIG. 6 shows a perspective of a wafer structure according to a fifth embodiment of the invention;

FIG. 7 shows a perspective of a wafer structure according to a sixth embodiment of the invention; and

FIG. 8 shows a perspective of a wafer structure according to a seventh embodiment of the invention.

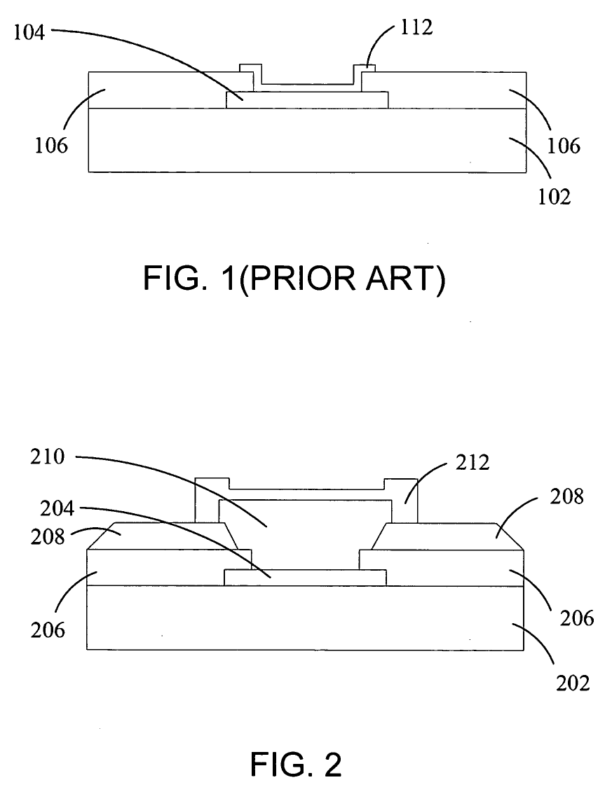

### DETAILED DESCRIPTION OF THE INVENTION

The invention provides a wafer structure with a buffer layer. A buffer layer is added to the wafer structure to enhance the structural strength of the wafer structure and avoid the ball coming off. Referring to FIG. 2, a perspective of a wafer structure according to a first embodiment of the invention is shown. According to the invention, the wafer structure comprises a wafer 202 having a first surface (the upper surface as indicated in FIG. 2). The first surface forms at least one pad 204 electrically connected with the wafer 202. Despite the fact that only one pad 204 is illustrated in FIG. 2, the first surface of the wafer 202 can form a plurality of pads 204, other electrical connection components or other electrical/electronic components. These are generally known techniques and are not repeated here. Besides, in a preferred embodiment of the invention, the pad 204 is made of aluminum or other related alloy due to the simple manufacturing process of forming an aluminum pad low cost. The pad on the wafer can be made of the material used in other similar techniques. However, the material used in the invention is not limited to the particular materials.

A passivation layer 206 made of a suitable insulation material or dielectric material is formed on and covers the first surface of the wafer 202 according to generally known techniques or manufacturing processes. The passivation layer 206 has a opening portion (not illustrated) corresponding to a pad 204 for exposing the pad 204 but covering a portion of the pad 204. The opening portion can be formed by the way of any known methods such as etching. According to the embodiment disclosed in FIG. 2, the circumference of the pad 204 is be covered by the passivation layer 206 due to the opening portion.

According to the invention, a layer of outer buffering member 208 is coated on the passivation layer 206 to provide better shock-absorbing and buffer ability for the wafer. The outer buffering member 208 also forms an opening portion corresponding to the opening portion formed on the passivation layer 206 for exposing the pad 204. According to a preferred embodiment of the invention, the outer buffering member 208 is made of polyimide whose softness property provides better shock-absorbing ability to absorb the impact caused by external force. According to the embodiment indicated in FIG. 2, the opening portion of the outer buffering member 208 is slightly larger than the opening portion of the passivation layer 206, so that a portion of the passivation layer 206 around the circumference of the opening portion and the pad 204 are exposed to the opening portion of the outer buffering member 208.

Besides, to provide a buffer, a layer of inner buffering member 210 is further coated on the pad 204 exposed to the opening portion of the passivation layer 206 and the outer buffering member 208. The inner buffering member 210 can be formed according to any generally known techniques. In a preferred embodiment of the invention, the inner buffering member 210 is formed on the pad 204 by electroless-plating aluminum, wherein the thickness of the inner buffering member 210 is at least larger than 3 micrometers, and the inner buffering member 210 further covers a portion of the passivation layer 206 and a portion of the outer buffering member 208. According to a preferred embodiment of the invention, the inner buffering member 210 is made of aluminum or an alloy thereof, and the thickness of the inner buffering member 210 is considerably increased in comparison to the pad 204, so that the upper surface of the inner buffering member 210 projects from the outer buffering member 208. The invention provides much better buffer ability than generally known techniques because aluminum is relatively softer than the material used in generally known techniques and the thickness of the inner buffering member 210 is considerably increased in the invention. The invention has another advantage in that the pad 204 is made of aluminum so that the inner buffering member 210 which is also made of aluminum can be easily formed on the pad 204 with excellent bonding.

An UBM 212 is formed on the inner buffering member 210 projecting from the outer buffering member 208. The UBM 212, which is usually formed by an adhesion layer, a barrier layer and a moisture layer, covers a portion of the outer buffering member 208 made of a material selected from a group consisting of nickel, gold, palladium, titanium, vanadium and an alloy thereof.

The outer buffering member 208 may completely or partially covers the passivation layer 206. The inner buffering member 210 may completely covers or does not cover the passivation layer 206. The inner buffering member 210 may completely covers, partially covers or does not cover the outer buffering member 208. Likewise, the UBM 212 may completely covers, partially covers or does not cover the outer buffering member 208 so as to provide different combinations.

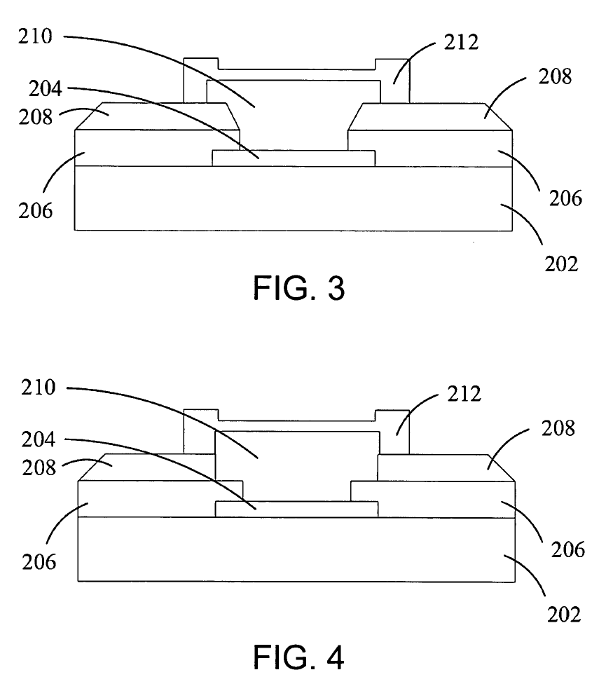

FIG. 3 shows a perspective of a wafer structure according to a second embodiment of the invention, wherein the outer buffering member 208 completely covers the passivation layer 206.

FIG. 4 shows a perspective of a wafer structure according to a third embodiment of the invention, wherein the inner buffering member 210 does not cover the outer buffering member 208.

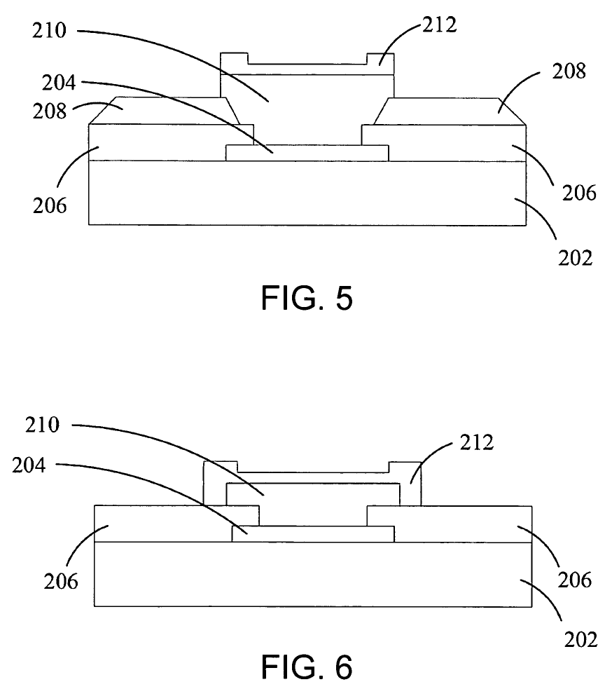

FIG. 5 shows a perspective of a wafer structure according to a fourth embodiment of the invention, wherein the UBM 212 does not cover the inner buffering member 210.

FIG. 6 shows a perspective of a wafer structure according to a fifth embodiment of the invention, wherein the outer buffering member 208 is omitted and only the thickness-increased inner buffering member 210 is left. Thus, the wafer structure according to the fifth embodiment comprises:

A wafer 202 comprising at least one pad 204 made from aluminum;

A passivation layer 206 disposed on the wafer 202 for partially exposing the at least one pad 204 and covering a portion of the pad 204;

An inner buffering member 210 formed by electroless-plating aluminum on the at least one pad 204, wherein the thickness of the inner buffering member 210 is at least larger than 3 micrometers, and the inner buffering member 210 further covers a portion of the passivation layer 206; and

An UBM 212 disposed on the inner buffering member 210, wherein the UBM 212 covers a portion of the passivation layer 206 made from a material selected from a group comprising nickel, gold, palladium, titanium, vanadium and an alloy thereof.

The inner buffering member 210 can completely cover, partially cover or not cover the passivation layer 206. Likewise, the UBM 212 can completely cover, partially cover or not cover the inner buffering member 210 so as to provide different combinations.

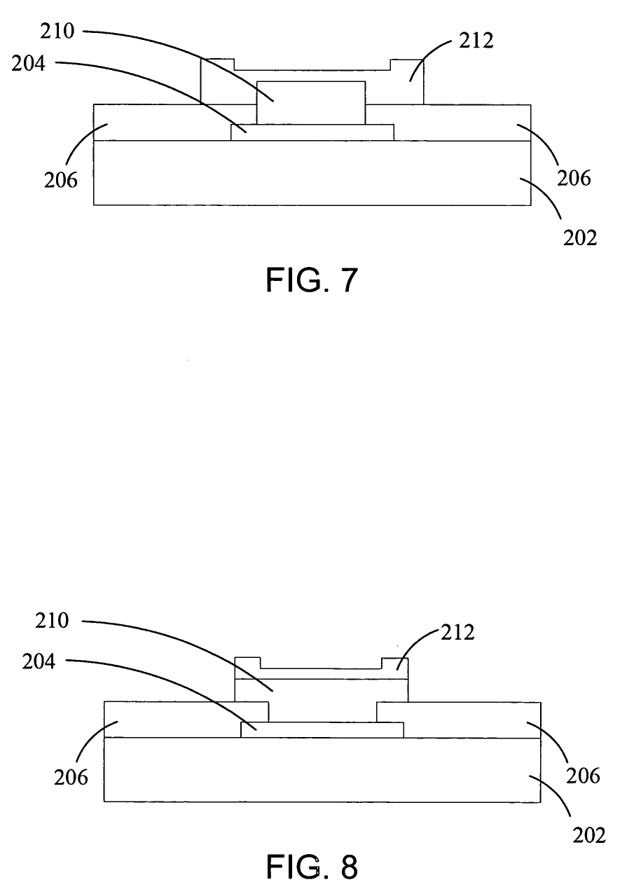

FIG. 7 shows a perspective of a wafer structure according to a sixth embodiment of the invention, wherein the inner buffering member 210 does not cover the passivation layer 206.

FIG. 8 a perspective of a wafer structure according to a seventh embodiment of the invention, wherein the UBM 212 does not cover the inner buffering member 210.

The invention has the following features: (a) Enhance the shock-absorbing ability of the wafer such that the conductive bumps will not crack easily. (b) Avoid the conductive bumps coming off easily.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A wafer structure with a buffer layer comprising:
a wafer comprising at least one pad;
a passivation layer disposed on the wafer for exposing the at least one pad;
an outer buffering member coated on the passivation layer;
an inner buffering member coated on the at least one pad; and
an under bump metallurgy (UBM) disposed on the inner buffering member.

2. The wafer structure with a buffer layer according to claim 1, wherein a portion of the passivation layer is further covered by the inner buffering member.

3. The wafer structure with a buffer layer according to claim 1, wherein the outer buffering member is further covered by the inner buffering member.

4. The wafer structure with a buffer layer according to claim 1, wherein the outer buffering member is further covered by the UBM.

5. The wafer structure with a buffer layer according to claim 1, wherein the UBM is made of a material selected from a group consisting of nickel, gold, palladium, titanium, vanadium and an alloy thereof.

6. The wafer structure with a buffer layer according to claim 1, wherein a portion of the pad is covered by the passivation layer.

7. The wafer structure with a buffer layer according to claim 1, wherein the pad is made of aluminum.

8. The wafer structure with a buffer layer according to claim 1, wherein the outer buffering member is made of polyimide.

9. The wafer structure with a buffer layer according to claim 1, wherein the inner buffering member is made of aluminum.

10. The wafer structure with a buffer layer according to claim 1, wherein the inner buffering member is formed by the way of electroless plating.

11. The wafer structure with a buffer layer according to claim 1, wherein the thickness of the inner buffering member is at least larger than 3 micrometers.

12. A wafer structure with a buffer layer, comprising:
a wafer comprising at least one pad;
a passivation layer disposed on the wafer for exposing the at least one pad;
an inner buffering member coated on the at least one pad; and
an under bump metallurgy (UBM) disposed on the inner buffering member.

13. The wafer structure with a buffer layer according to claim 12, wherein a portion of the passivation layer is further covered by the inner buffering member.

14. The wafer structure with a buffer layer according to claim 12, wherein a portion of the passivation layer is further covered by the UBM.

15. The wafer structure with a buffer layer according to claim 12, wherein the UBM is made of a material selected from a group consisting of nickel, gold, palladium, titanium, vanadium and an alloy thereof.

16. The wafer structure with a buffer layer according to claim 12, wherein a portion of the pad is further covered by the passivation layer.

17. The wafer structure with a buffer layer according to claim 12, wherein the pad is made of aluminum.

18. The wafer structure with a buffer layer according to claim 12, wherein the inner buffering member is made of aluminum.

19. The wafer structure with a buffer layer according to claim 12, wherein the inner buffering member is formed by the way of electroless plating.

20. The wafer structure with a buffer layer according to claim 12, wherein the thickness of the inner buffering member is at least larger than 3 micrometers.
